(19) United States
(12) Patent Application Publication
(10) Pub. No.: US 2006/0292898 A1
(43) Pub. Date: Dec. 28, 2006

(54) Electrical interconnection system

(75) Inventors: Kevin R. Meredith, Cedar Park, TX (US); Alexander W. Barr, Austin, TX (US); Steven Feldman, Cedar Park, TX (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/165,401

(22) Filed: Jun. 23, 2005

(51) Int. Cl. H05K 1/00

(52) U.S. Cl. 439/65

(57) ABSTRACT

An electrical interconnection system includes a printed circuit board having a receiving cavity therein. At least one circuit trace is located on a side wall of the cavity. An electrical connector is configured for insertion into the receiving cavity. The electrical connector has an electrical contact positioned to contact the at least one circuit trace when inserted into the receiving cavity.

### BACKGROUND

The present invention relates to electrical interconnection systems, and particularly to electrical interconnection systems for use with a printed circuit board.

In many electronic devices, it is desired to connect a printed circuit board to an electrical cable, a flexible circuit, or to another printed circuit board. As electronic devices become smaller, less space is available for making the connection to the printed circuit board. In keeping with the trend toward ever smaller electronic devices, an electrical interconnection system that occupies a minimum amount of area on the surface of the printed circuit board is highly desirable.

### SUMMARY

One aspect of the invention described herein provides an electrical interconnection system. In one embodiment according to the invention, the electrical interconnection system comprises a printed circuit board having a top surface and a bottom surface. A receiving cavity, defined by at least one side wall, extends from the top surface toward the bottom surface of the printed circuit board. At least one circuit trace is located on the at least one side wall of the cavity. An electrical connector is configured for insertion into the receiving cavity. The electrical connector has an electrical contact positioned to contact the at least one circuit trace when inserted into the receiving cavity.

In another embodiment according to the invention, the electrical interconnection system comprises a cavity formed in a planar printed circuit board and a plug connector. The cavity comprises a circumferential edge surface transverse to a planar surface of the printed circuit board, and a plurality of electrical contacts on the circumferential edge surface of the cavity. The plug connector comprises a dielectric body configured for insertion into the cavity, and a plurality of electrical contacts retained on the dielectric body. The electrical contacts of the plug connector are positioned to engage the electrical contacts of the cavity when the plug connector is inserted into the cavity.

Another aspect of the invention described herein provides an electrical connector for connection to a printed circuit board. In one embodiment according to the invention, the electrical connector is for connection to a printed circuit board having a cavity formed therein, the cavity having an electrical contact on an inside edge surface thereof. The electrical connector comprises a dielectric body configured for insertion into the printed circuit board cavity, and an electrical contact retained at an outer surface of the dielectric body. The electrical contact of the connector is positioned to engage the electrical contact in the cavity when the connector is inserted into the cavity.

Another aspect of the invention described herein provides a method of connecting an electrical connector to a printed circuit board. In one embodiment, the method comprises providing a printed circuit board having a cavity therein, the cavity defined by an edge surface transverse to a plane of the printed circuit board and having an electrical contact on the edge surface. A connector is inserted into the cavity, the connector having an electrical contact at an outer surface thereof, the electrical contact of the connector positioned to engage the electrical contact in the cavity when the connector is inserted into the cavity.

### BRIEF DESCRIPTION OF THE DRAWINGS

FIG. 1 is a perspective illustration of one embodiment of an electrical interconnection system in a disengaged condition according to the invention.

FIG. 2 is a perspective cross-sectional illustration of the electrical interconnection system of FIG. 1 in an engaged condition.

FIG. 3 is a perspective illustration of another embodiment of the electrical interconnection system of FIG. 1, in use with two printed circuit boards.

FIG. 4 is a cross-sectional illustration of the electrical interconnection system of FIG. 3.

FIG. 5 is a perspective illustration of another embodiment of an electrical interconnection system in a disengaged condition according to the invention.

FIG. 6 is a perspective cross-sectional illustration of the electrical interconnection system of FIG. 5 in an engaged condition.

FIG. 7 is a perspective illustration of another embodiment of the electrical interconnection system of FIG. 5, in use with two printed circuit boards.

FIG. 8 is a cross-sectional illustration of the electrical interconnection system of FIG. 7.

FIG. 9 is a perspective illustration of another embodiment of an electrical interconnection system in a disengaged condition according to the invention.

FIG. 10 is an illustration of another embodiment of an electrical interconnection system in use with two printed circuit boards, according to the invention.

FIG. 11 is an illustration showing curvilinear side walls of a receiving cavity in a printed circuit board, according to an embodiment of the invention.

FIG. 12 is an illustration showing side walls of a receiving cavity in a printed circuit board inclined relative to the plane of the printed circuit board, according to an embodiment of the invention.

FIG. 13 is an illustration of exemplary polarization and keying features of an electrical interconnection system according to an embodiment of the invention.

### DETAILED DESCRIPTION

In the following detailed description of the preferred embodiments, reference is made to the accompanying drawings that form a part hereof. The accompanying drawings show, by way of illustration, specific embodiments in which the invention may be practiced. It is to be understood that other embodiments may be utilized, and structural or logical changes may be made without departing from the scope of the present invention. The following detailed description, therefore, is not to be taken in a limiting sense, and the scope of the present invention is defined by the appended claims.

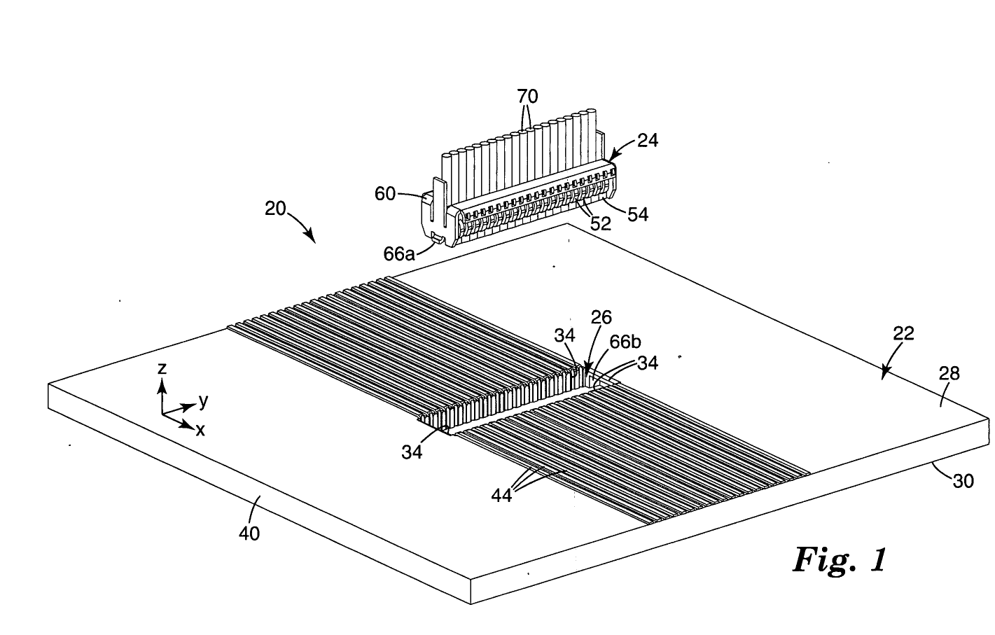

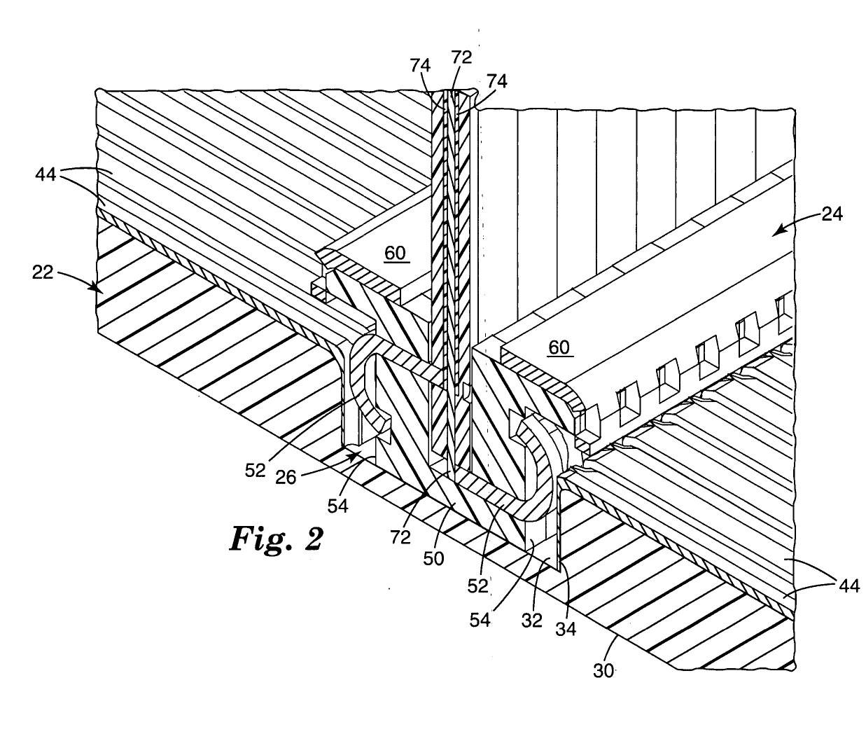

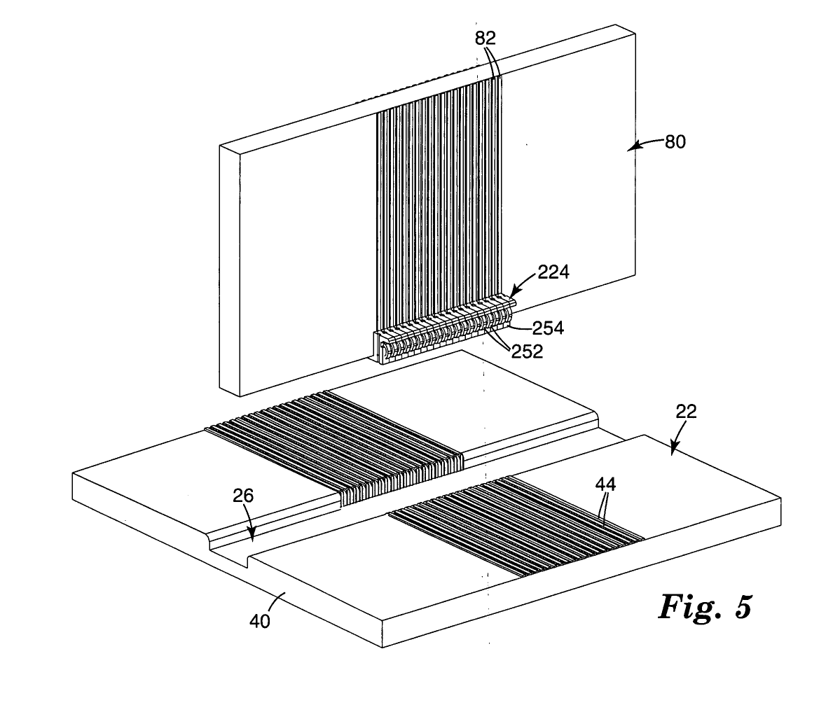

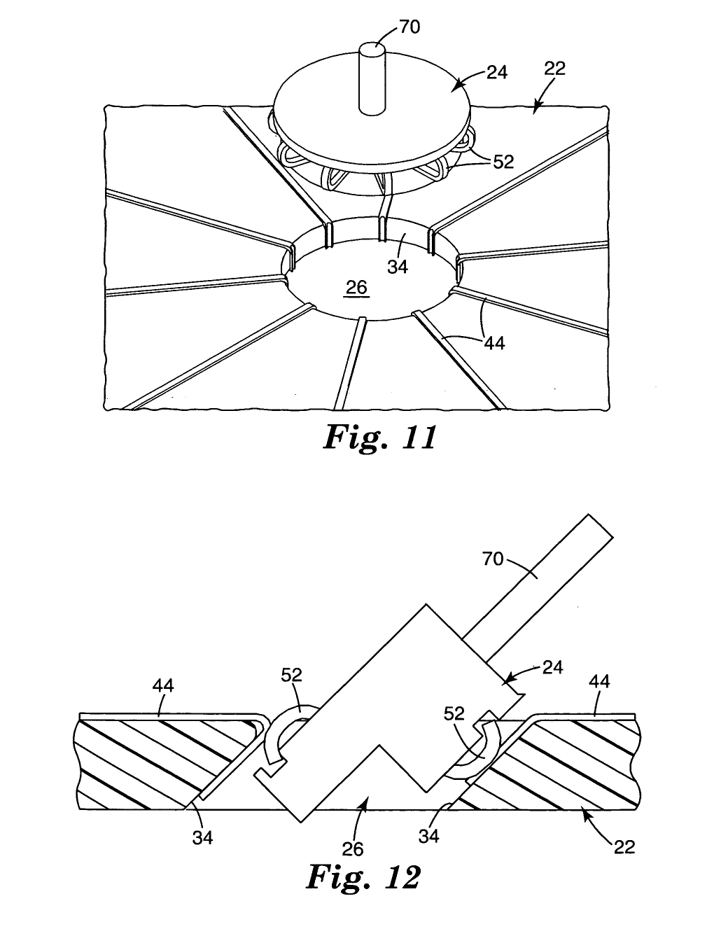

FIGS. 1 and 2 illustrate one embodiment of an electrical interconnection system 20 in accordance with the present invention. The electrical interconnection system 20 includes a printed circuit board 22 and a mating electrical connector 24. The printed circuit board 22 defines an X-Y plane. A socket or receiving cavity 26 extends into the printed circuit board 22 from a top surface 28 of the board toward a bottom surface 30 of the board in a direction transverse to the X-Y plane. In one embodiment, the receiving cavity 26 extends only partially through the printed circuit board 22 and includes a bottom surface 32. In another embodiment, the receiving cavity 26 extends completely through the printed circuit board 22. The peripheral shape of the receiving cavity 26 is defined by one or more side walls 34. The receiving cavity 26 may have any desired or suitable peripheral shape, including rectilinear shapes and curvilinear shapes (FIG. 11). In one embodiment, the side walls 34 of the receiving cavity 26 are substantially normal to the X-Y plane of the printed circuit board 22. In another embodiment, one or more side walls 34 of the receiving cavity 26 are inclined relative to the X-Y plane of the printed circuit board 22 (FIG. 12). In one embodiment, the periphery of the receiving cavity 26 is positioned away from the circumferential edges 40 of the printed circuit board 22. In another embodiment, the receiving cavity 26 intersects a circumferential edge 40 of the printed circuit board 22, such that at least one side the receiving cavity 26 is open to an edge 40 of the printed circuit board 22 (FIG. 5).

The printed circuit board 22 includes one or more circuit traces 44. In one embodiment, the circuit traces 44 are located on top surface 28 and/or bottom surface 30 of the printed circuit board 22. In another embodiment, circuit traces 44 are positioned within an interior layer (not shown) of the printed circuit board 22. At least one circuit trace 44 of the printed circuit board 22 extends onto at least one of the side walls 34 of the receiving cavity 26, such that the portion of the circuit trace 44 on the side wall 34 of the receiving cavity 26 extends in a direction transverse to the X-Y plane of the printed circuit board 22. Portions of circuit traces 44 on the side wall 34 of the receiving cavity 26 may be referred to herein generally as “vertical circuit traces” (even if the side wall 34 is not vertical or normal to the X-Y plane of the printed circuit board 22). In the illustrated embodiment, circuit traces 44 are positioned on two opposing side walls 34 of the receiving cavity 26. In other embodiments, circuit traces 44 are positioned on only one side of the receiving cavity 26, on adjacent sides of the receiving cavity 26, or on each side of the receiving cavity 26, for example.

The circuit traces 44 on the side walls 34 of the receiving cavity 26 (“vertical circuit traces”) are formed using any suitable method. In one embodiment, a side wall 34 is plated with a conductive material, and then unwanted portions of the conductive material are removed by mechanical and/or chemical means to form the vertical circuit traces. In another embodiment, one or more through-holes are created in the printed circuit board 22 at the edge of a yet-to-be-formed side wall 34. The through-holes are plated with conductive material, and then the side wall 34 is formed by milling away material and leaving portions of the plated through-holes to form the vertical traces.

The plug-type electrical connector 24 is configured for insertion into the receiving cavity 26. The electrical connector 24 includes an insulative dielectric body 50 having one or more electrical contacts 52, which may be signal or ground contacts, retained at one or more outer side surfaces 54 of the dielectric body 50. The electrical contacts 52 are positioned to make contact with the circuit traces 44 on the side walls 34 of the receiving cavity 26 when the electrical connector 24 is inserted into the receiving cavity 26. The electrical connector 24 provides any necessary compliance between the mated printed circuit board 22 and the electrical connector 24. Engagement forces between the electrical contacts 52 of the connector 24 and the circuit traces 44 in the receiving cavity 26 are substantially normal to the plane of the side wall 34 supporting circuit traces 44. Thus, when the side walls 34 are normal to the X-Y plane of the printed circuit board 22, the engagement forces between the electrical contacts 52 of the connector 24 and the circuit traces 44 in the receiving cavity 26 are substantially parallel to the X-Y plane of the printed circuit board 22. In one embodiment, the electrical contacts 52 are resilient members that deflect when the electrical connector 24 is inserted into the receiving cavity 26. In the illustrated embodiments, electrical contacts 52 are U-shaped members which deflect inwardly when the electrical connector 24 is inserted into the receiving cavity 26 (FIG. 2). In another embodiment, the dielectric body 50 of the electrical connector 24 is itself mechanically compliant, such that the dielectric body 50 deforms as the electrical connector 24 is inserted into the receiving cavity 26. The electrical connector 24 optionally includes conductive shield members 60 positioned on the dielectric body 50 above the plane of the printed circuit board 22 to provide improved impedance control for the interconnection system 20.

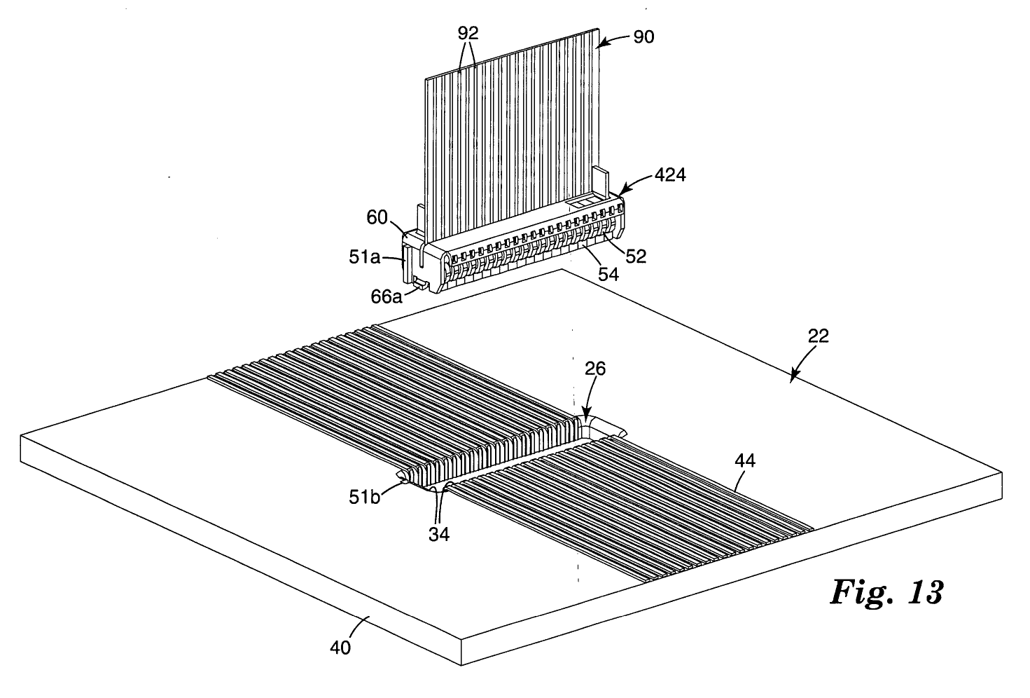

In one embodiment, the electrical connector 24 and receiving cavity 26 include polarization and/or keying features 51a, 51b, to prevent incorrect orientation of the electrical connector 24 within the receiving cavity 26. Exemplary polarization features are illustrated in FIG. 13. In one embodiment, the electrical connector 24 and receiving cavity 26 may also have cooperating latch or retention features to maintain the electrical connector 24 within the receiving cavity 26. For example, as best seen in FIG. 1, connector 24 includes tabs 66a for engaging recesses 66b in printed circuit board 22.

The electrical connector 24 of FIGS. 1 and 2 is shown connected to a plurality of electrical cables 70, although in one embodiment connector 24 and cavity 26 are sized and configured for use with a single cable 70. The cables 70 may be individual coaxial cables or twinaxial cables, or a ribbon cable, for example. The electrical contacts 52 of the electrical connector 24 are electrically connected to conductive members of the cables 70, as is known in the art. For example, the electrical contacts 52 of the electrical connector 24 may be attached to signal conductors 72 and/or ground conductors 74 of the cables 70 by soldering, crimping, or insulation displacement methods. An insulating layer (not shown) separates signal conductor 72 from ground conductor 74.

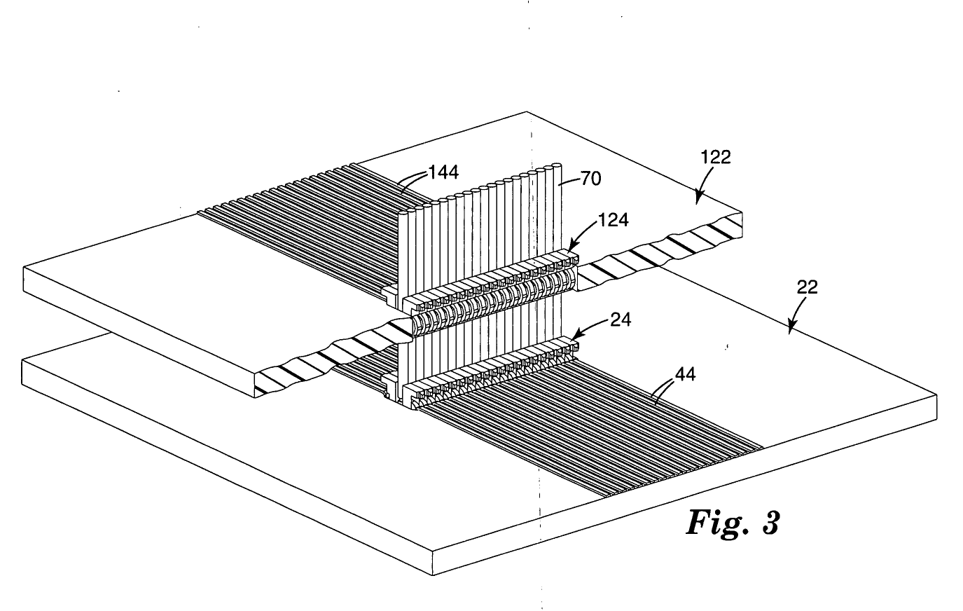

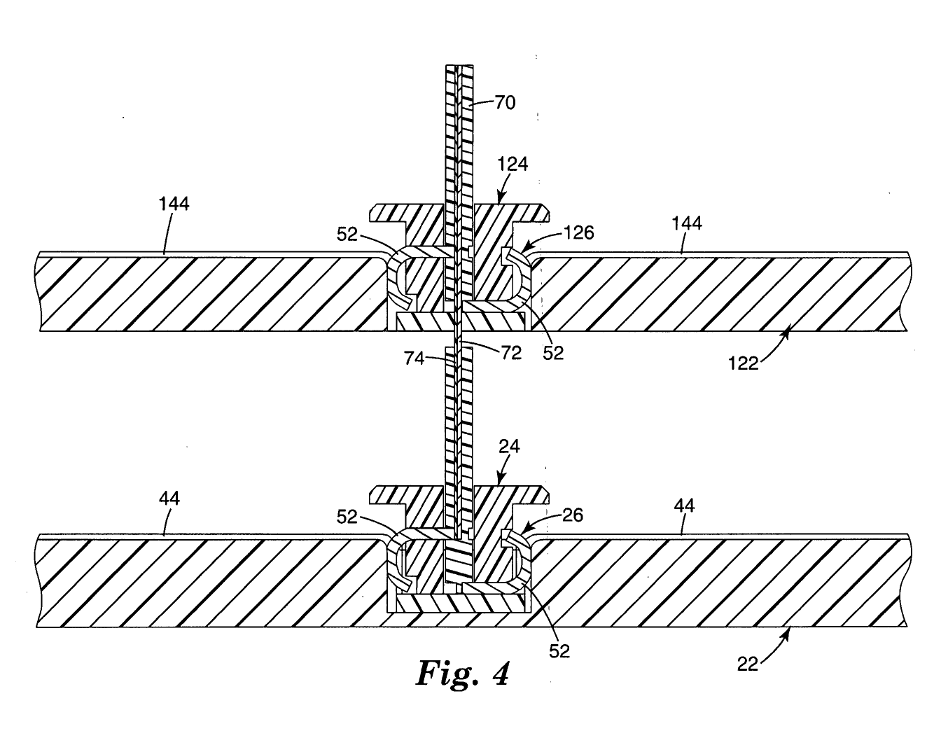

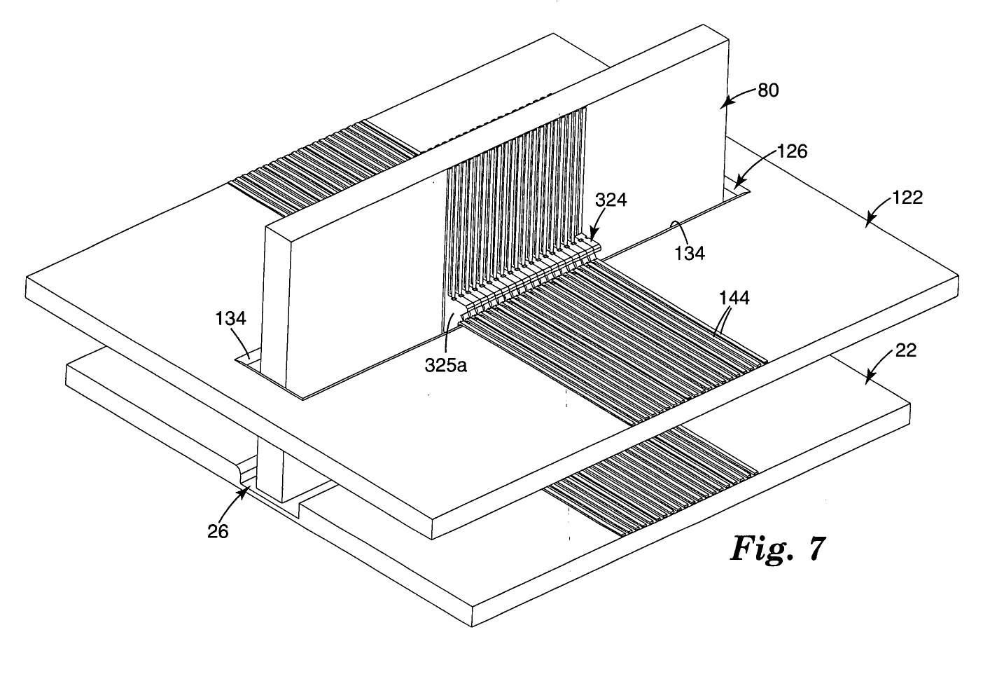

The electrical interconnection system of FIGS. 1 and 2 includes a single electrical connector 24 and printed circuit board 22. However, in another embodiment according to the invention, the interconnection system includes more than one electrical connector 24 and printed circuit board 22. Referring to FIGS. 3 and 4, the electrical interconnection system 20 of FIGS. 1 and 2 is shown with the cables 70 attached to a second electrical connector 124 for mating with a second printed circuit board 122 having a receiving cavity 126 extending completely therethrough. The receiving cavity 126 of the second printed circuit board 122 includes at least one circuit trace 144 on at least one side wall 134 (best shown if FIG. 7) of the receiving cavity 126. The second electrical connector 124 is configured for attachment to the cables 70 and for insertion into the receiving cavity 126 of the second printed circuit board 122. The second electrical connector 124 is constructed in a manner similar to that described above, but allows the cables 70 to extend through the second electrical connector 124 to the first electrical connector 24. In this manner, the individual cables 70 may selectively be connected to one or both of the first and second printed circuit boards 22, 122, respectively. This can be accomplished, for example, by opening a “window” in the cable jacket, spreading apart a portion of the ground conductor 74 and insulating layer (not shown) within the window, and terminating the signal contact 52 to the signal conductor 72 through the window.

Referring now to FIGS. 5-8, another embodiment of an electrical interconnection system according to the invention is illustrated, where elements similar to those described with respect to FIGS. 1-4 are similarly numbered. In the embodiment of FIGS. 5-8, electrical connector 224 is configured for attachment to a printed circuit board 80 (“daughtercard 80”), rather than to electrical cables. The printed circuit board 22 and receiving cavity 26 are similar to those described above with respect to FIGS. 1-4, except the length of the receiving cavity 26 may be longer than the length of the electrical connector 224 to accommodate the daughtercard 80, if the daughtercard 80 is larger than the length of the electrical connector 224. In one embodiment, receiving cavity 26 extends to at least one edge 40 of printed circuit board 22.

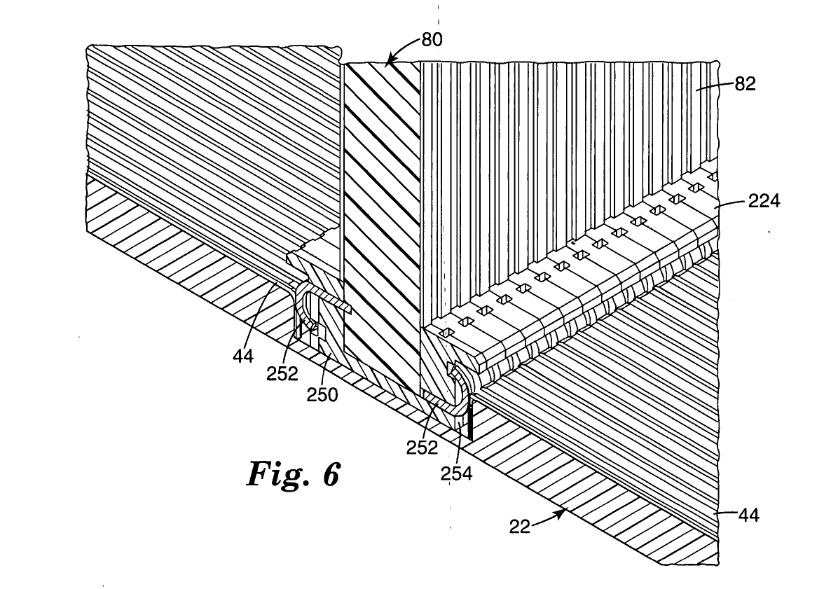

Referring to FIG. 6, electrical connector 224 includes insulative dielectric body 250 having one or more electrical contacts 252 retained at one or more outer side surfaces 254 of the dielectric body 250. The electrical contacts 252 are electrically connected to circuit traces 82 on daughtercard 80, and are positioned to make contact with the circuit traces 44 on the side walls 34 of the receiving cavity 26 when the electrical connector 224 is inserted into the receiving cavity 26. The electrical connector 224 provides any necessary compliance between the mated printed circuit board 22 and the electrical connector 224. Engagement forces between the electrical contacts 252 of the connector 224 and the circuit traces 44 in the receiving cavity 26 are substantially normal to the plane of the side wall 34 supporting circuit traces 44. Thus, when the side walls 34 are normal to the X-Y plane of the printed circuit board 22, the engagement forces between the electrical contacts 252 of the connector 24 and the circuit traces 44 in the receiving cavity 26 are substantially parallel to the X-Y plane of the printed circuit board 22. In one embodiment, the electrical contacts 252 are resilient members that deflect when the electrical connector 24 is inserted into the receiving cavity 26. In the illustrated embodiments, electrical contacts 252 are U-shaped members which deflect inwardly when the electrical connector 224 is inserted into the receiving cavity 26. In another embodiment, the dielectric body 250 of the electrical connector 224 is itself mechanically compliant, such that the dielectric body 250 deforms as the electrical connector 224 is inserted into the receiving cavity 26. The electrical connector 224 optionally includes conductive shield members positioned on the dielectric body 250 to provide improved impedance control for the interconnection system.

In one embodiment, the electrical connector 224 and receiving cavity 26 include polarization features as described above with respect to FIG. 13 to prevent incorrect orientation of the electrical connector 224 within the receiving cavity 26. The electrical connector 224 and receiving cavity 26 may also have cooperating latch or retention features to maintain the electrical connector 224 within the receiving cavity 26, as described above with respect to FIG. 1.

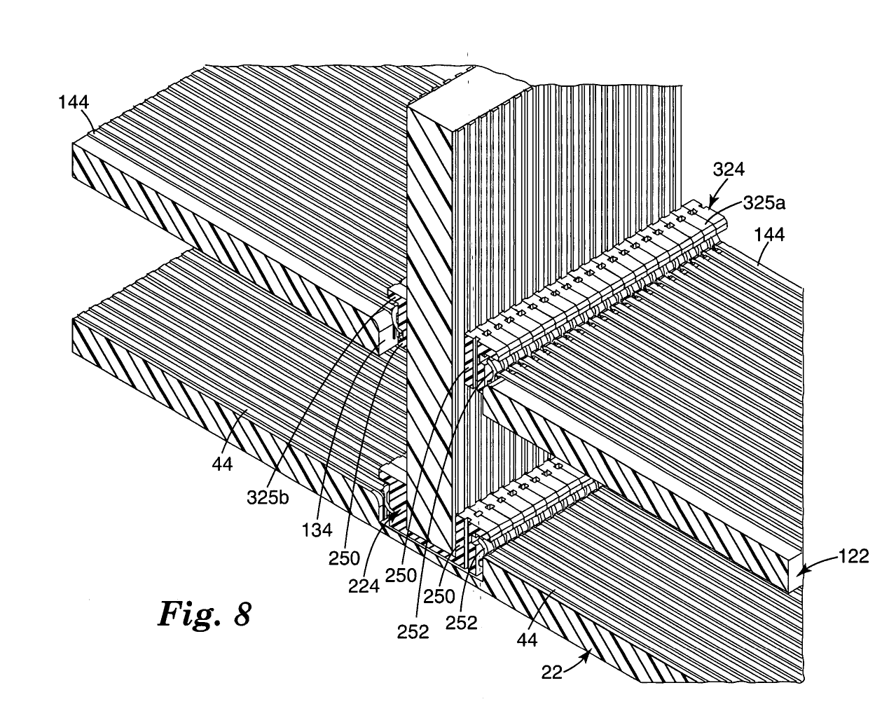

The electrical interconnection system of FIGS. 5 and 6 includes a single electrical connector 224. However, in another embodiment according to the invention, the interconnection system includes more than one electrical connector 224. Referring to FIGS. 7 and 8, the daughtercard 80 is shown connected to a second electrical connector 324 for mating with a second printed circuit board 122 having a receiving cavity 126 extending completely therethrough. The receiving cavity 126 of the second printed circuit board 122 includes at least one circuit trace 144 on at least one side wall 134 of the receiving cavity 126. The second electrical connector 324 is configured for attachment to the daughtercard 80 and for insertion into the receiving cavity 126 of the second printed circuit board 122. The second electrical connector 324 is constructed in a manner similar to that described above, but allows the daughtercard 80 to extend through the second printed circuit board 122 to the first electrical connector 224. In this manner, circuit traces 82 on the daughtercard 80 may selectively be connected to one or both of the first and second printed circuit boards 22, 122, respectively. In the illustrated embodiment, the second electrical connector 324 comprises separate connector halves 325a, 325b mounted on opposite sides of daughtercard 80, with each connector half 325a, 325b having a portion of dielectric body 250 and electrical contacts 252. In another embodiment, the second electrical connector 324 may comprise a single unit.

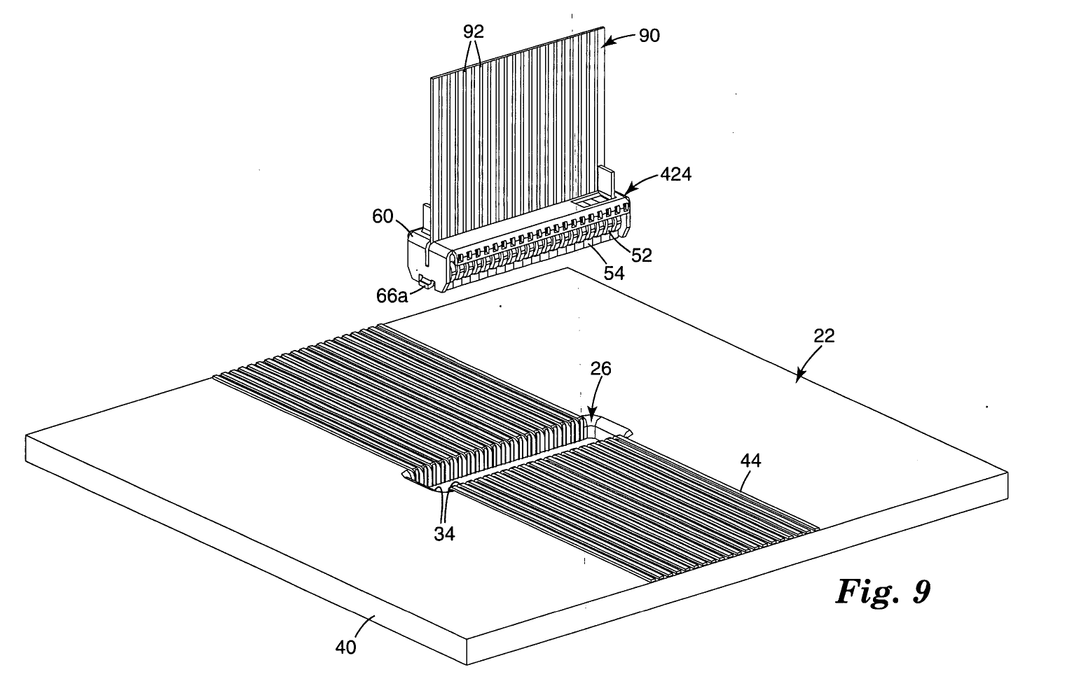

Referring now to FIG. 9, another embodiment of an electrical interconnection system according to the invention is illustrated, where elements similar to those described with respect to FIGS. 1-8 are similarly numbered. In the embodiment of FIG. 9, an electrical connector 424 is configured for attachment to a flexible circuit 90. The printed circuit board 22 and receiving cavity 26 are similar to those described above with respect to FIGS. 1-4. The electrical connector 424 is substantially identical to electrical connector 24 described above for use with electrical cables 70, but with dielectric body 50 and electrical contacts 52 modified for attachment to a flexible circuit and circuit traces 92 thereon. In another embodiment, similar to electrical connector 324 for use with printed circuit boards, electrical connector 424 comprises separate connector halves mounted on opposite sides of flexible circuit 90. The electrical interconnection system of FIG. 9 illustrates a single electrical connector 424. However, in another embodiment according to the invention, the interconnection system includes more than one electrical connector 424 as described with reference to FIGS. 3, 4, 7 and 8.

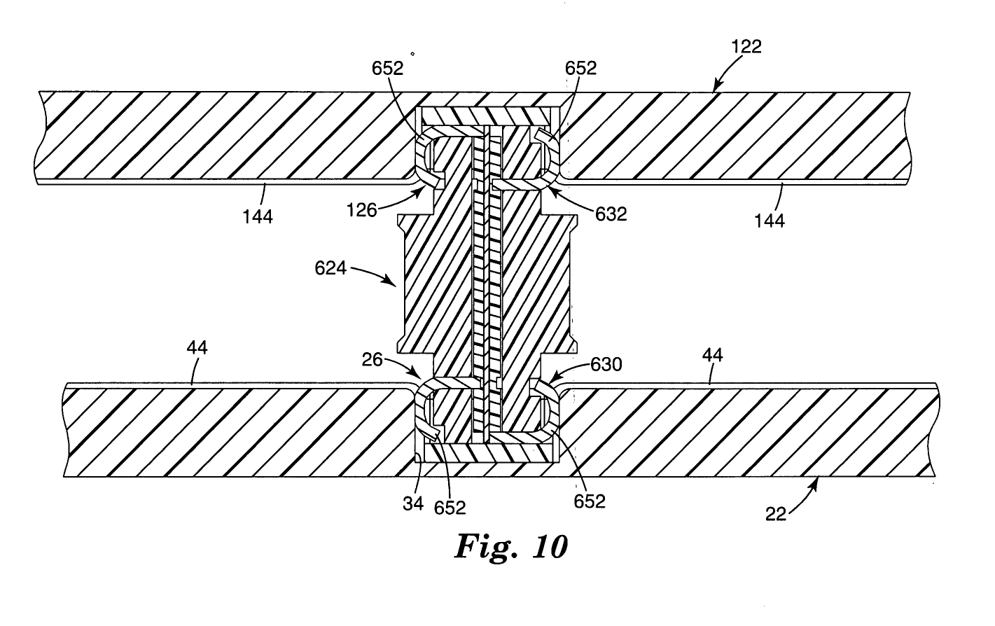

Referring now to FIG. 10, another embodiment of an electrical interconnection system according to the invention is illustrated. The electrical connector 624 is formed as a mezzanine connector for joining two or more printed circuit boards 22, 122. The electrical connector 624 has a first portion 630 configured for insertion into a receiving cavity 26 of the first printed circuit board 22, and a second portion 632 configured for insertion into a receiving cavity 126 of the second printed circuit board 122. The first and second portions 630, 632 each have electrical contacts 652 positioned to engage the circuit traces 44, 144 on the side walls 34, 134 of the corresponding receiving cavity 26, 126 when the connector 624 is inserted into the receiving cavities 26, 126. Conductive paths (not shown) through the connector 624 electrically interconnect electrical contacts 652 at firs and second portions 630, 632. Although only two printed circuit boards 22, 122 are illustrated, the electrical connector 624 can be configured for connection to additional printed circuit boards in a manner consistent with that illustrated. In another embodiment, the mezzanine connector 624 is further configured for connection to electrical cables 70, flexible circuit 90 or another printed circuit board 80, as described above with respect to FIGS. 1-9.

In each of the embodiments described herein, all polymer parts are molded from suitable thermoplastic material having the desired mechanical and electrical properties for the intended application. The conductive metal parts are made from, for example, plated copper alloy material, although other suitable materials will be recognized by those skilled in the art. In one embodiment, the interconnection system materials, geometry and dimensions are all designed to maintain a specified impedance throughout the system.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the mechanical, electromechanical, and electrical arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

What is claimed is:

1. An electrical interconnection system comprising:
a printed circuit board having a top surface and a bottom surface;
a receiving cavity in the printed circuit board extending from the top surface toward the bottom surface of the printed circuit board, the receiving cavity defined by at least one side wall;
at least one circuit trace on the at least one side wall of the cavity; and
an electrical connector configured for insertion into the receiving cavity, the electrical connector having an electrical contact positioned to contact the at least one circuit trace when inserted into the receiving cavity.

2. The electrical interconnection system of claim 1, wherein the electrical connector is connected to one of an electrical cable, a flexible circuit, and another printed circuit board.

3. The electrical interconnection system of claim 1, wherein the electrical connector includes a biasing member for retaining the electrical connector within the receiving cavity.

4. The electrical interconnection system of claim 1, wherein the electrical contact comprises a biasing member.

5. The electrical interconnection system of claim 1, wherein the receiving cavity extends partially through the printed circuit board from the first surface to the second surface of the printed circuit board.

6. The electrical interconnection system of claim 1, wherein the receiving cavity extends fully through the printed circuit board from the first surface to the second surface of the printed circuit board.

7. The electrical interconnection system of claim 1, wherein the at least one side wall of the receiving cavity is substantially normal to a plane of the top surface of the printed circuit board.

8. The electrical interconnection system of claim 1, wherein the at least one side wall of the receiving cavity is inclined relative to a plane of the top surface of the printed circuit board.

9. The electrical interconnection system of claim 1, wherein the receiving cavity and the electrical connector include mating polarization features.

10. The electrical interconnection system of claim 1, wherein the at least one wall of the receiving cavity defines at least a portion of a curvilinear receiving cavity.

11. The electrical interconnection system of claim 1, wherein the at least one wall of the receiving cavity defines at least a portion of a rectilinear receiving cavity.

12. The electrical interconnection system of claim 1, further comprising:
a second printed circuit board having a top surface and a bottom surface;
a second receiving cavity in the second printed circuit board extending from the top surface toward the bottom surface of the second printed circuit board, the second receiving cavity defined by at least one side wall; and
at least one circuit trace on the at least one side wall of the second receiving cavity;
wherein the electrical connector is configured for insertion into the first and second receiving cavities, the electrical connector having electrical contacts positioned to contact the circuit traces of the first and second receiving cavities when inserted into the first and second receiving cavities.

13. The electrical interconnection system of claim 1, further comprising:
a second printed circuit board having a top surface and a bottom surface;
a second receiving cavity in the second printed circuit board extending from the top surface toward the bottom surface of the second printed circuit board, the second receiving cavity defined by at least one side wall;
at least one circuit trace on the at least one side wall of the second receiving cavity; and
a second electrical connector configured for insertion into the second receiving cavity, the second electrical connector having electrical contacts positioned to contact the circuit traces of the second receiving cavity when inserted into the second receiving cavity;
wherein the first and second electrical connectors are both connected a common one of an electrical cable, a flexible circuit, and another printed circuit board.

14. An electrical interconnection system comprising:
a cavity formed in a planar printed circuit board, the cavity comprising:
a circumferential edge surface transverse to a planar surface of the printed circuit board; and
at least one electrical contact on the circumferential edge surface of the cavity; and
a plug connector comprising:
a dielectric body configured for insertion into the cavity; and
at least one electrical contact retained on the dielectric body, the at least one electrical contact of the plug connector positioned to engage the at least one electrical contact of the cavity when the plug connector is inserted into the cavity.

15. The electrical interconnection system of claim 14, wherein the circumferential edge surface of the cavity defines a closed shape.

16. The electrical interconnection system of claim 14, wherein the circumferential edge surface of the cavity defines an open shape.

17. The electrical interconnection system of claim 14, wherein the electrical contacts of the plug connector comprise biasing members.

18. The electrical interconnection system of claim 17, wherein the biasing members exert forces substantially parallel to the planar surface of the printed circuit board.

19. The electrical interconnection system of claim 14, wherein the electrical contacts are positioned on at least two sides of the cavity and plug connector.

20. An electrical connector for connection to a printed circuit board having a cavity formed therein, the cavity having an electrical contact on an inside edge surface thereof, the electrical connector comprising;
a dielectric body configured for insertion into the printed circuit board cavity;
an electrical contact retained at an outer surface of the dielectric body, the electrical contact of the connector positioned to engage the electrical contact in the cavity when the connector is inserted into the cavity.

21. The electrical connector of claim 20, wherein the printed circuit board cavity has electrical contacts on opposing inside edge surfaces thereof, and wherein the electrical connector further comprises electrical contacts on opposing sides of the dielectric body, the electrical contacts of the connector positioned to engage the electrical contacts in the cavity when the connector is inserted into the cavity.

22. The electrical connector of claim 20, wherein the dielectric body comprises a first portion configured for insertion into a cavity of a first printed circuit board, and a second portion configured for insertion into a cavity of a second printed circuit board, wherein the first and second portions each have an electrical contact positioned to engage the electrical contact in the corresponding cavity of the first and second printed circuit boards when the connector is inserted into the cavities.

23. The electrical connector of claim 20, wherein engagement forces between the electrical contact in the cavity and the electrical contact of the electrical connector are substantially parallel to a plane defined by the printed circuit board

24. The electrical connector of claim 20, wherein the electrical contact of the electrical connector is mechanically compliant.

25. The electrical connector of claim 20, wherein the dielectric body is mechanically compliant.
